(19) United States
(12) Patent Application Publication
(10) Pub. No.: US 2008/0266824 A1
(43) Pub. Date: Oct. 30, 2008

(54) PAD AND CIRCUIT BOARD, ELECTRONIC DEVICE USING SAME

(75) Inventor: TING-YU WANG, Foshan (CN)

Correspondence Address: PCE INDUSTRY, INC.;ATT. CHENG-JU CHIANG, 458 E. LAMBERT ROAD, FULLERTON, CA, 92835, US

(73) Assignees: PREMIER IMAGE TECHNOLOGY(CHINA) LTD., Foshan City (CN); HON HAI PRECISION INDUSTRY CO., LTD., Tu-Cheng (TW)

(21) Appl. No.: 11/875,133

(22) Filed: Oct. 19, 2007

(30) Foreign Application Priority Data
Apr. 29, 2007 (CN) 200710200564.X

(51) Int. Cl. H05K 7/00

(52) U.S. Cl. 361/767

(57) ABSTRACT

A pad for soldering a lead of an electronic element includes a solder portion and one or more non-contiguous extending portions. The solder portion is configured for positioning the lead of the electronic element thereon and has a size and shape substantially equal to the size and shape of the footprint of the lead. The one or more non-contiguous extending portions extending from the solder portion and configured for providing additional solder paste in the soldering process. The pad can limit the position of the leads of the electronic element in the solder portion, thus ensuring accurate positioning of the electronic element.

### BACKGROUND

1. Technical Field

The present invention relates to surface mount technology (SMT), and more particularly, to an improved pad used for mounting an electronic element on a circuit board.

2. Description of Related Art

In recent years, SMT is widely used in electronic device manufacturing for mounting electronic elements to a circuit board. These electronic elements, such as resistors, capacitors, inductances and so on, are connected to a circuit board by pads.

The pads are arranged on the circuit board in a matched relationship with leads of the electronic elements. The pads have different configurations due to varied configurations of the leads of the electronic elements, such as a circle, a square, a teardrop, and so on. The size of the pads is usually bigger than the size of the leads of the electronic elements corresponding to the pads. When soldering the electronic elements to the circuit board, the leads of the electronic elements may slide on the pads. As a result, accurate positioning of the electronic elements can't be assured. For some electronic elements, such as image sensors, accurate positioning on the circuit board may be critical. If the size of the pads is equal to or smaller than that of the leads of the electronic elements corresponding to the pads, solder paste printed on the pads for soldering the electronic elements thereto may be too little. Accordingly, some of the leads may become disconnected from corresponding pads of the circuit board.

What is needed, therefore, is an improved pad capable of accurately positioning the electronic element and not become disconnected from the leads of the electronic element.

### SUMMARY

In accordance with one embodiment, a pad for soldering a lead of an electronic element includes a solder portion and one or more non-contiguous extending portions. The solder portion is configured for positioning the lead of the electronic element thereon and has a size and shape substantially equal to the size and shape of the footprint of the lead. The one or more non-contiguous extending portions extend from the solder portion and are configured (i.e., structured and arranged) to provide sufficient solder paste in the soldering process.

### BRIEF DESCRIPTION OF THE DRAWING

Many aspects of the present electronic device can be better understood with reference to the following drawings. The components in the drawing are not necessarily drawn to scale, the emphasis instead being placed upon clearly illustrating the principles of the present electronic device. Moreover, in the drawings, like reference numerals designate corresponding parts throughout the several views.

FIG. 1 is a schematic, exploded view of an electronic device according to a first embodiment;

FIG. 2 is a schematic view of the electronic device of FIG. 1 after assembly;

FIG. 3 is a schematic plan view of a circuit board according to a first embodiment;

FIG. 4 is a schematic plan view of a circuit board according to a second embodiment; and

FIG. 5 is a schematic plan view of a circuit board according to a third embodiment.

### DETAILED DESCRIPTION OF THE EMBODIMENTS

The embodiments will now be described in detail below with reference to the drawings.

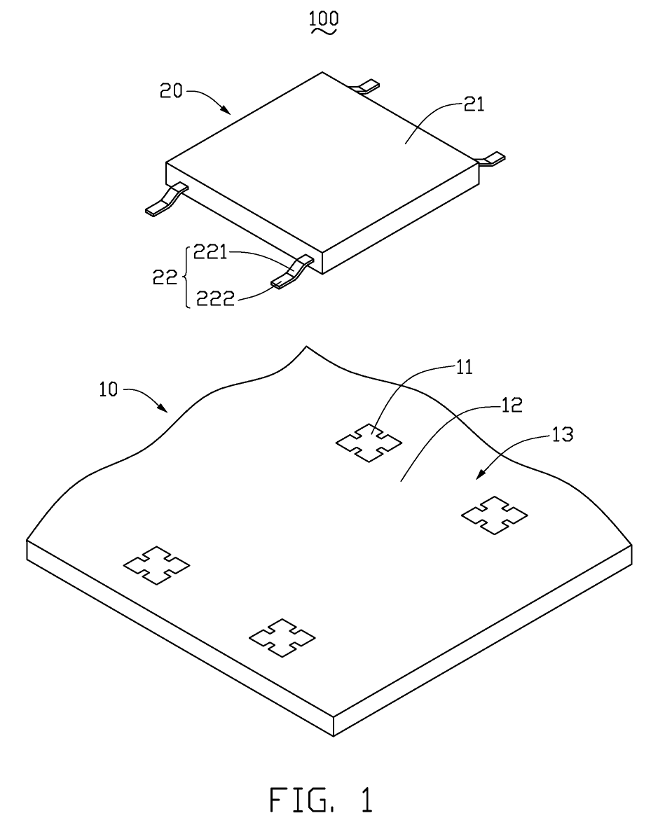

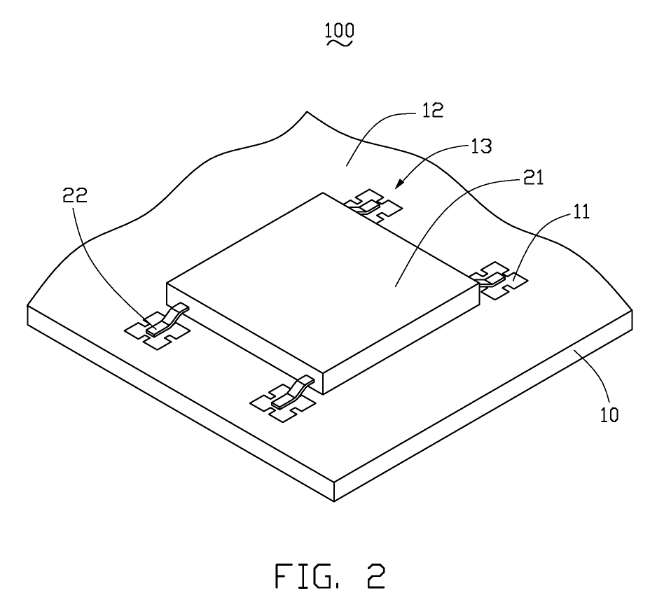

Referring to FIG. 1 and FIG. 2, an electronic device 100 according to a first embodiment includes a circuit board 10 and at least one electronic element 20 mounted on the circuit board 10. The circuit board 10 and the electronic element 20 are soldered so as to electrically connect.

The electronic element 20 can be a resistor, a capacitor, an integrated circuit, an image sensor or the like. Preferably, the electronic element 20 should be accurately positioned on the circuit board 20. The electronic element 20 includes a main body 21 and a number of leads 22 electrically connected with the main body 21. The main body 21 has circuits sealed therein.

In the present embodiment, the electronic element 20 has four leads 22. Each lead 22 includes an extending portion 221 and a contact portion 222. The extending portion 221 extends from a side surface of the main body 21 and is bent towards the bottom of the electronic element 20 with its distal end connecting with the contact portion 222. The contact portion 222 is essentially parallel with the circuit board 10 and can be soldered to the circuit board 10.

In the present embodiment, the circuit board 10 is a printed circuit board laminate composed of multiple layers of non-conductive material and conductive traces sandwiched together to form a rigid planar structure. A number of pads 11 reside on a surface 13 of the circuit board 10 and are surrounded by a solder mask 12, which also resides on the surface 13 of the circuit board 10.

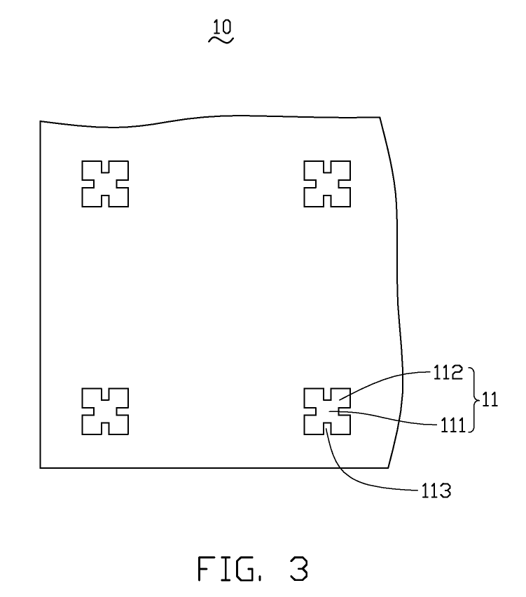

Referring to FIG. 3, the pads 11 are corresponding to the footprints of the contact portions 222 of the leads 22 and configured for soldering the contact portions 222 thereon in order to electrically connect the circuit board 10 and the electronic element 20. The pads 11 can be formed on the circuit board 10 by chemical etching etc. In the present embodiment, each of the pads 11 is generally quadrate-shaped. Each of the pads 11 has a solder portion 111 and four separate extending portions 112 extending respectively from four corners of the solder portion 111. The solder portion 111 is configured for soldering the corresponding contact portion 222 of the lead 22 and has a size and shape substantially equal to the size and shape of the footprint of the contact portion 222, and four void 113 are defined at sides of the extending portions 112 adjacent to the solder portion 111 such that the solder mask 12 extends into the voids 113 to contact with the periphery edges of the solder portion 11 and prevent the corresponding footprint sliding to the extending portions 112 in the soldering process, so that, the contact portion 222 can't slide from the solder portion 111 to the extending portions 112 and the electronic element 20 is capable of being positioned on the surface of the circuit board 10 accurately. The extending portions 112 extending from each of the solder portions 111 are configured for increasing the area of the corresponding pad 11, and providing more solder paste for soldering the electronic element 20 to the circuit board 10. Accordingly, accidental electrical disconnection between the circuit board 10 and the electronic element 20 can be prevented. Preferably, the four extending portions 112 are uniformly distributed around the solder portion 111.

The solder mask 12 extends around a periphery of the group of the pads 11 provided for the electronic element 20. In particular, the material of the solder mask 12 can be a solder-resist material.

In the present embodiment, each of the pads 11 of the circuit board 10 includes the solder portion 111 and the extending portions 112. The extending portions 112 can support a sufficient amount of solder paste to be printed on the pad 11, so that, the size of the solder portion 111 can be decreased. Therefore, when the electronic element 20 is mounted on the circuit board 10, the contact portions 222 of the electronic element 20 can be held in the solder portion 111 and breakage of the electrical connection between the circuit board 10 and the electronic element 20 can be prevented. The electronic element 20 can be accurately positioned on the circuit board 10.

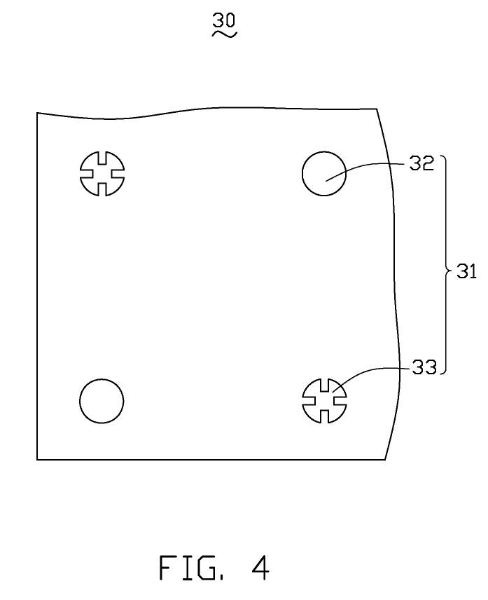

Referring to FIG. 4, a circuit board 30 according to a second embodiment includes a pad array 31 with two first pads 32 and two second pads 33. The two second pads 33 are disposed opposite vertical angles of the pad array 31. The first pads 32 are fully round pads. The second pads 33 are similar to the pads 11 of the circuit board 10 except for having a circular outline.

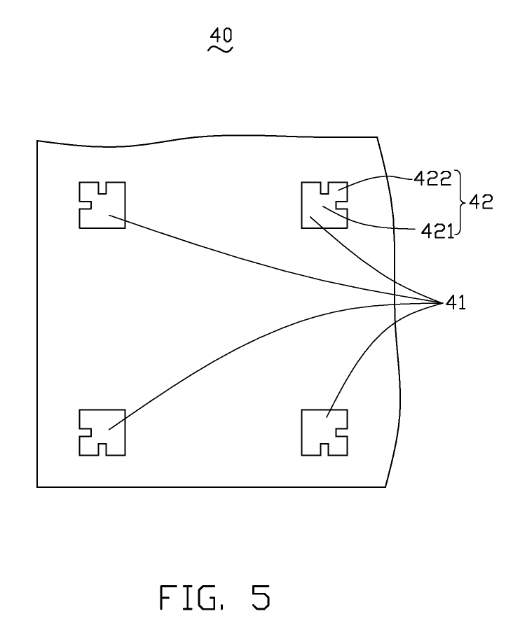

Referring to FIG. 5, a circuit board 40 according to a third embodiment includes a pad array 41 with four pads 42 arranged symmetrically about a center of an area defined by the four pads 42. Each of the pads 42 includes a solder portion 421 and an extending portion 422. The solder portion 421 has the same function as the solder portion 111 according to the first embodiment and the extending portion 422 has the same function as the extending portions 112 according to the first embodiment. The minimum length and width of the solder portion 421 is substantially equal to the length and width of the footprints of the leads of the electronic element 21.

It should be understood that the number of the extending portions 422 of the pad 42 can be two, three, five and so on. The number of the extending portions 422 of the pad 42 can be decided as needed and is not limited to the particular embodiments described.

While certain embodiments have been described and exemplified above, various other embodiments will be apparent to those skilled in the art from the foregoing disclosure. The present invention is not limited to the particular embodiments described and exemplified but is capable of considerable variation and modification without departure from the scope of the appended claims.

What is claimed is:

1. A pad for soldering a lead of an electronic element, comprising:
a solder portion configured for positioning the lead of the electronic element thereon, the solder portion having a size and shape substantially equal to the size and shape of the footprint of the lead; and
one or more non-contiguous extending portions extending from the solder portion and configured for providing additional solder paste in the soldering process.

2. The pad as claimed in claim 1, wherein the minimum length and width of the solder portion is equal to the length and width of the footprint of the lead of the electronic element.

3. The pad as claimed in claim 1, wherein the pad is formed on a circuit board by chemical etching.

4. A circuit board comprising:
a pad array disposed on a surface of the circuit board configured for soldering leads of an electronic element on the circuit board, the pad array comprising a plurality of pads; and
a solder mask disposed on the surface around periphery of the pads; wherein
at least one of the pads comprises a solder portion configured for soldering the corresponding lead thereon, an extending portion extending from a periphery of the solder portion for supporting solder paste thereon in the soldering process of the corresponding lead, and at least one void being defined at one side of the extending portion adjacent to the solder portion such that the solder mask extends into the at least one void to prevent the corresponding lead sliding to the extending portion in the soldering process, whereby the electronic element is capable of being positioned on the surface of the circuit board accurately.

5. The circuit board as claimed in claim 4, wherein each of the pads is formed on the circuit board by chemical etching.

6. The circuit board as claimed in claim 4, wherein the pad array is arranged on the surface of the circuit board in a rectangular fashion, and the at least one pad is two pads at two diagonal corners of the pad array respectively.

7. An electronic device comprising a circuit board and an electronic element mounted thereon, the circuit board comprising:
a pad array on a surface of the circuit board configured for soldering leads of the electronic element on the circuit board, the pad array including a plurality of pads with at least one pad comprising:
a solder portion configured for positioning the lead of the electronic element thereon, the solder portion having a size and shape substantially equal to the size and shape of the footprint of the lead;
one or more non-contiguous extending portions extending from the solder portion and configured for providing additional solder paste in the soldering process; and
a solder mask disposed on the surface of the circuit board extending around a periphery of the pad array.

8. The electronic device as claimed in claim 7, wherein the at least one pad has a plurality of extending portions, the extending portions uniformly distributed around the solder portion.

9. The electronic device as claimed in claim 7, wherein each of the pads is formed by chemical etching.

10. The electronic device as claimed in claim 7, wherein the pad array is arranged on the surface of circuit board in a rectangular fashion, and the at least one pad is two pads at two diagonal corners of the pad array respectively.

11. The electronic device as claimed in claim 7, wherein the at least one pad defines at least one void at one side of the extending portion adjacent to the solder portion such that the solder mask extends into the at least one void to contact with a periphery edge of the solder portion and prevent the corresponding lead from sliding to the extending portion in the soldering process.
